(19) United States
(12) Patent Application Publication
(10) Pub. No.: US 2002/0017957 A1
(43) Pub. Date: Feb. 14, 2002

(54) Oscillator with low-noise collector current and switching circuit therefor

(75) Inventor: Yasumasa Nishiyama, Fukushima-ken (JP)

Correspondence Address: BRINKS HOFER GILSON & LIONE, P.O. BOX 10395, CHICAGO, IL, 60610, US

(73) Assignee: Alps Electric Co., Ltd.

(21) Appl. No.: 09/967,083

(22) Filed: Sep. 28, 2001

(30) Foreign Application Priority Data
Feb. 10, 2000 (JP) 2000-306630

(51) Int. Cl. H03L 7/00

(52) U.S. Cl. 331/2

(57) ABSTRACT

An oscillator includes an oscillation transistor; a power supply resistor for supplying a bias voltage to the base of the oscillation transistor; and an NPN transistor whose collector is connected to the power supply and whose emitter is connected to the power supply resistor. A capacitor is connected between the base of the NPN transistor and the ground. A resistor is connected between the power supply and the base of the NPN transistor.

### BACKGROUND OF THE INVENTION

1. Field of the Invention

The present invention relates to oscillators and switching circuits therefor that are used in, for example, cellular phones and the like.

2. Description of the Related Art

FIG. 3 shows the structure of a conventional oscillator. The collector of an oscillation transistor 61 is connected to a power supply terminal 62, and the emitter of the oscillation transistor 61 is grounded via an emitter transistor 63. A feedback capacitor 64 is connected between the base and the emitter of the oscillation transistor 61, and a feedback capacitor 65 is connected between the emitter of the oscillation transistor 61 and the ground. A resonant circuit 66 is connected to the base of the oscillation transistor 61. A bias voltage is supplied by resistors 67 and 68 provided between the power supply terminal 62 and the ground. A voltage supplied to a control terminal 69 is applied to a varactor diode 66a in the resonant circuit 66, thereby changing the oscillation frequency. An oscillation signal is output from an output terminal 70 connected to the emitter of the oscillation transistor 61. A voltage is supplied to the power supply terminal 62 from a regulator 71.

When two such oscillators for use in different cellular phone systems are provided in a cellular phone, one oscillator is switched to an operating state, while the other oscillator is switched an inoperative state. In such a case, a selector switch (not shown) is provided between the power supply terminal 62 and each oscillator, and the selector switch is used to change the voltage applied to each oscillator.

In the above-described oscillator, when noise is superposed on the power supply voltage supplied from the regulator 71, the noise is directly applied to the collector and the base of the oscillation transistor 61. As a result, a noise component is superposed on a collector current, and the carrier-to-noise (C/N) ratio of the oscillation signal deteriorates. Since two oscillators are interchanged by the switching of the power supply voltage, a selector switch with large current capacitance is necessary.

### SUMMARY OF THE INVENTION

Accordingly, it is an object of the present invention to provide an oscillator in which noise of a collector current is reduced without reducing a voltage applied to the collector of an oscillation transistor even when noise is superposed on a power supply voltage supplied from a regulator.

It is another object of the present invention to provide an oscillator switching circuit which can switch between two oscillators by using small current while reducing noise of collector current of two oscillation transistors.

In order to achieve the foregoing objects, according to an aspect of the present invention, an oscillator is provided including an oscillation transistor; an NPN transistor for supplying a bias voltage from the emitter thereof to the base of the oscillation transistor; a capacitor connected between the base of the NPN transistor and the ground; and a resistor for introducing a base current to flow through the base of the NPN transistor.

Accordingly, a ripple filter is formed by the NPN transistor, the resistor, and the capacitor. Without reducing the voltage of the collector of the oscillation transistor, ripples at the emitter of the NPN transistor are significantly attenuated to a small value compared with ripples at the base. Thus, ripples of the collector current flowing through the oscillation transistor are greatly reduced. The oscillation signal is hardly influenced by the ripples, and the C/N ratio is increased.

According to another aspect of the present invention, an oscillator switching circuit is provided including a first oscillator including a first oscillation transistor; and a second oscillator including a second oscillation transistor. The first oscillator includes a first NPN transistor for supplying a bias voltage from the emitter thereof to the base of the first oscillation transistor; a first capacitor connected between the base of the first NPN transistor and the ground; and a first resistor for introducing a current to flow through the base of the first NPN transistor; and hence the first NPN transistor is switched between ON and OFF. The second oscillator includes a second NPN transistor for supplying a bias voltage from the emitter thereof to the base of the second oscillation transistor; and a second capacitor connected between the base of the second NPN transistor and the ground. A PNP transistor which is turned ON or OFF in accordance with the ON/OFF of the first NPN transistor is provided. The collector of the PNP transistor and the base of the second NPN transistor are connected by a second resistor. The emitter of the first NPN transistor and the base of the PNP transistor are connected by a third resistor.

Accordingly, the operation of the oscillator can be switched by switching a ripple filter for supplying a bias voltage to the base of each oscillation transistor while the power supply voltage is directly applied to the collector. Since the switching can be made by changing the voltage of the base of the first NPN transistor, the current required to make the switching is small, and the operation is simple.

A bias resistor may be connected between the emitter of the first NPN transistor and the base of the first oscillation transistor. The resistance ratio between the third resistor and the bias resistor may be set so that the first oscillation transistor is not activated by a voltage applied to the base of the first oscillation transistor when the PNP transistor is turned ON.

Accordingly, only the second oscillation transistor can be reliably activated.

### BRIEF DESCRIPTION OF THE DRAWINGS

FIG. 1 is a circuit diagram showing the structure of an oscillator according to an embodiment of the present invention;

FIG. 2 is a circuit diagram showing the structure of an oscillator switching circuit according to another embodiment of the present invention; and

FIG. 3 is a circuit diagram showing the structure of a conventional oscillator.

### DESCRIPTION OF THE PREFERRED EMBODIMENTS

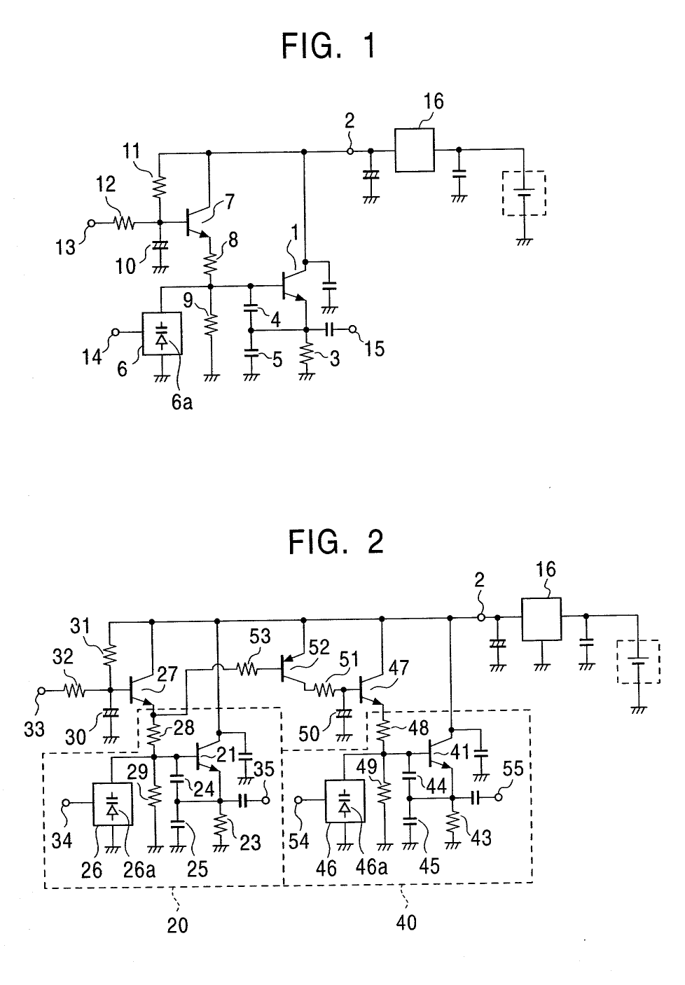

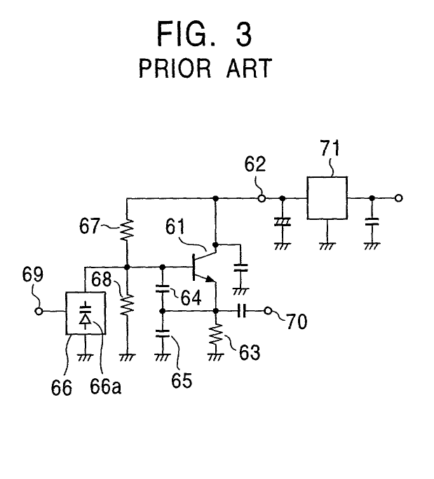

Referring to FIG. 1, an oscillator according to an embodiment of the present invention is described. The collector of an oscillation transistor 1 is connected to a power supply terminal 2, and the emitter of the oscillation transistor 1 is grounded through an emitter transistor 3. A feedback capacitor 4 is connected between the base and the emitter of the oscillation transistor 1, and a feedback capacitor 5 is connected between the emitter of the oscillation transistor 1 and the ground. A resonant circuit 6 is connected to the base of the oscillation transistor 1.

Between the power supply terminal 2 and the base of the oscillator transistor 1, an NPN transistor 7 whose collector is connected to the power supply terminal 2 and a first bias resistor 8 connected between the emitter of the NPN transistor 7 and the base of the oscillation transistor 1 are provided. A second bias resistor 9 is connected between the base of the oscillation transistor 1 and the ground. The base of the NPN transistor 7 is grounded through a capacitor (electrolytic capacitor) 10 which has a relatively large capacitance. Also, the base of the NPN transistor 7 is connected to the power supply terminal 2 through a resistor 11. The base of the NPN transistor 7 is connected to a switching terminal 13 through a resistor 12.

A voltage supplied to a control terminal 14 is applied to a varactor diode 6a in the resonant circuit 6, thereby changing the oscillation frequency. An oscillation frequency is output from an output terminal 15 connected to the emitter of the oscillation transistor 1.

A voltage from batteries (not shown) is input to a regulator 16, and a constant voltage output from the regulator 16 is supplied to the power supply terminal 2.

Arranged as described above, when the switching terminal 13 is released, the NPN transistor 7 is turned ON. The NPN transistor 7, the resistor 11, and the capacitor 10 form a ripple filter. Ripples at the emitter of the NPN transistor 7 are significantly attenuated to a small value compared with ripples at the base. Thus, ripples of the collector current flowing through the oscillation transistor 1 are greatly reduced. The oscillation signal is hardly influenced by the ripples, and the C/N ratio is increased.

In order to make the oscillator inoperative, the switching terminal 13 is grounded. In the present invention, the ripple filter is provided in series with the bias resistors 8 and 9 for supplying a bias voltage to the base of the oscillation transistor 1. Thus, the power supply voltage applied to the collector of the oscillation transistor 1 is not reduced.

FIG. 2 shows an oscillator switching circuit according to another embodiment of the present invention. The switching circuit switches between two oscillators 20 and 40. The two oscillators 20 and 40 are included in a cellular phone which can be commonly used in cellular phones using different systems. The first oscillator 20 is used in the Personal Communications Services (PCS) system used in the United States, and the second oscillator 40 is used in the Advanced Mobile Phone Service (AMPS) system.

In the first oscillator 20, the collector of a first oscillation transistor 21 is connected to the power supply terminal 2, and the emitter of the first oscillation transistor 21 is grounded through an emitter resistor 23. A feedback capacitor 24 is connected between the base and the emitter of the first oscillation transistor 21, and a feedback capacitor 25 is connected between the emitter of the first oscillation transistor 21 and the ground. A first resonant circuit 26 is connected to the base of the first oscillation transistor 21.

Between the power supply terminal 2 and the base of the oscillation transistor 21, a first NPN transistor 27 whose collector is connected to the power supply terminal 2 and a first bias resistor 28 which is connected between the emitter of the first transistor 27 and the base of the first oscillation transistor 21 are provided. A second bias resistor 29 is connected between the base of the first oscillation transistor 21 and the ground. The base of the first NPN transistor 27 is grounded by a first capacitor 30 (such as an electrolytic capacitor) which has a relatively large capacitance, and the base of the NPN transistor 27 is connected to the power supply terminal 2 through a first resistor 31. The base of the first NPN transistor 27 is connected to a switching terminal 33 through a resistor 32.

A voltage supplied to a first control terminal 34 is applied to a first varactor diode 26a in the first resonant circuit 26, thereby changing the oscillation frequency. An oscillation signal is output from a first output terminal 35 which is connected to the emitter of the first oscillation transistor 21.

Similarly in the second oscillation transistor 40, the collector of a second oscillation transistor 41 is connected to the power supply terminal 2, and the emitter of the second oscillation transistor 41 is grounded through an emitter resistor 43. A feedback capacitor 44 is connected between the base and the emitter of the second oscillation transistor 41, and a feedback capacitor 45 is connected between the emitter of the second oscillation transistor 41 and the ground. A second resonant circuit 46 is connected to the base of the second oscillation transistor 41.

Between the power supply terminal 2 and the base of the second oscillation transistor 41, a second NPN transistor 47 whose collector is connected to the power supply terminal 2 and a third bias resistor 48 which is connected between the emitter of the second NPN transistor 47 and the base of the second oscillation transistor 41 are provided. A fourth bias resistor 49 is connected between the base of the second oscillation transistor 41 and the ground. The base of the second NPN transistor 47 is grounded by a second capacitor 50 (such as an electrolytic capacitor) which has a relatively large capacitance.

A PNP transistor 52 whose emitter is connected to the power supply terminal 2 is provided. The collector of the PNP transistor 52 is connected to the base of the second NPN transistor 47 through a second resistor 51, and the base of the PNP transistor 52 is connected to the emitter of the first NPN transistor 27 through a third resistor 53.

A voltage supplied to a second control terminal 54 is applied to a varactor diode 46a in the second resonant circuit 46, thereby changing the oscillation frequency. An oscillation signal is output from a second output terminal 56 connected to the emitter of the second oscillation transistor 41.

A voltage from batteries (not shown) is input to the regulator 16, and a constant voltage output from the regulator 16 is supplied to the power supply terminal 2.

Arranged as described above, when the switching terminal 33 is released or is switched to a high-level voltage, the first NPN transistor 27 is turned ON. The voltage of the emitter of the first NPN transistor 27 becomes substantially the voltage of the power supply terminal 2, and the bias voltage is supplied to the base of the first oscillation transistor 21 by the bias resistors 28 and 29, thereby activating the first oscillator 20.

As a result, the first NPN transistor 27, the first capacitor 30, and the first resistor 31 form a ripple filter. Ripples of the current flowing through the collector of the first oscillation transistor 21 are greatly reduced, and hence an oscillation signal with a high C/N ratio is generated.

At this time, the PNP transistor 52 is turned OFF, and hence the second NPN transistor 47 is also turned OFF. Thus, no bias voltage is applied to the base of the second oscillation transistor 41, and the second oscillator 41 is not activated.

In contrast, when the switching terminal 33 is grounded, the first NPN transistor 27 is turned OFF (needless to say, the resistance ratio between the resistors 31 and 32 should be set that way). The PNP transistor 52 is turned ON, and also the second NPN transistor 47 is turned ON. As a result, the second NPN transistor 47, the second capacitor 50, and the second resistor 51 form a ripple filter. The bias voltage is supplied to the base of the second oscillation transistor 41 by the bias resistors 48 and 49. Thus, the second oscillator 40 is activated, and an oscillation signal with a large C/N ratio is generated.

When the PNP transistor 52 is turned ON, the voltage is supplied to the base of the first oscillation transistor 21 by the bias resistors 28 and 29. If the resistance of the third resistor 53 is set to a large value compared with that of the bias resistor 28, the voltage of the base is reduced. As a result, the first oscillation transistor 21 is not activated.

As described above, the operation of the oscillator can be switched by switching the ripple filter for supplying a bias voltage to the base of each oscillation transistor. Since the switching can be made by changing the voltage of the base of the first NPN transistor 27, the current required to make the switching is small, and the operation is simple.

What is claimed is:

1. An oscillator comprising:
an oscillation transistor;
an NPN transistor for supplying a bias voltage from the emitter thereof to the base of the oscillation transistor;
a capacitor connected between the base of the NPN transistor and the ground; and
a resistor for introducing a base current to flow through the base of the NPN transistor.

2. An oscillator switching circuit comprising:
a first oscillator comprising a first oscillation transistor; and
a second oscillator comprising a second oscillation transistor;
wherein the first oscillator comprises a first NPN transistor for supplying a bias voltage from the emitter thereof to the base of the first oscillation transistor; a first capacitor connected between the base of the first NPN transistor and the ground; and a first resistor for introducing a current to flow through the base of the first NPN transistor; and hence the first NPN transistor is switched between ON and OFF;
the second oscillator comprises a second NPN transistor for supplying a bias voltage from the emitter thereof to the base of the second oscillation transistor; and a second capacitor connected between the base of the second NPN transistor and the ground;
a PNP transistor which is turned ON or OFF in accordance with the ON/OFF of the first NPN transistor is provided;
the collector of the PNP transistor and the base of the second NPN transistor are connected by a second resistor; and
the emitter of the first NPN transistor and the base of the PNP transistor are connected by a third resistor.

3. An oscillator switching circuit according to claim 2, wherein:
a bias resistor is connected between the emitter of the first NPN transistor and the base of the first oscillation transistor; and
the resistance ratio between the third resistor and the bias resistor is set so that the first oscillation transistor is not activated by a voltage applied to the base of the first oscillation transistor when the PNP transistor is turned ON.
